(19) United States
(12) Patent Application Publication
(10) Pub. No.: US 2026/0026346 A1
(43) Pub. Date: Jan. 22, 2026

(54) DIAMOND COATING FOR SEMICONDUCTOR

(71) Applicant: Advanced Diamond Holdings, LLC, Beltsville, MD (US)

(72) Inventors: John P. Ciraldo, Clarksburg, MD (US); Joshua T. Blackketter, Laurel, MD (US)

(21) Appl. No.: 19/277,038

(22) Filed: Jul. 22, 2025

Related U.S. Application Data
(60) Provisional application No. 63/674,046, filed on Jul. 22, 2024.

(51) Int. Cl. H01L 23/373; H01L 21/02

(52) U.S. Cl. CPC H01L 23/3732; H01L 21/02115; H01L 21/02175; H01L 21/022; H01L 21/02274; H01L 21/0228

(57) ABSTRACT

A method for thermal management of semiconductor devices provides a semiconductor material. A beryllium oxide (BeO) layer is epitaxially grown over the semiconductor material. A polycrystalline diamond coating is deposited over the BeO layer.

### PRIORITY

This patent application claims priority from provisional U.S. patent application No. 63/674,046, filed Jul. 22, 2024, entitled, “DIAMOND COATING FOR SEMICONDUCTOR,” and naming John Ciraldo as inventor, the disclosure of which is incorporated herein, in its entirety, by reference.

### FIELD

Illustrative embodiments of the invention generally relate to thermal management of semiconductor devices and, more particularly, various embodiments of the invention relate to a diamond coating deposited on a semiconductor device.

### BACKGROUND

A semiconductor device generates heat during operation. Excess heat limits the operational ratings of the semiconductor device. Gallium nitride (GaN) is an important material for a number of semiconductor applications, particularly power electronics applications having high power or high frequency requirements. The ratings of GaN semiconductor devices are constrained by the heat generated by the device during operation. Increasing the rate at which heat is dissipated from the GaN semiconductor device may increase the power rating or frequency rating of the GaN semiconductor device. One way to dissipate heat is to use highly thermally conductive substrates.

### SUMMARY OF VARIOUS EMBODIMENTS

In accordance with one embodiment of the invention, a method for thermal management of semiconductor devices provides a semiconductor material. A beryllium oxide (BeO) layer is epitaxially grown over the semiconductor material. A polycrystalline diamond coating is deposited over the BeO layer.

In various embodiments, the semiconductor material may include silicon, and/or gallium nitride. In some embodiments, the semiconductor material may be one or more semiconductor devices.

The diamond layer may have a thickness of 1-5 microns. In some embodiments, the diamond coating may be greater than 0.5 microns and/or less than 10 microns.

The semiconductor material may comprise a semiconductor device. The semiconductor material may be grown using a first growth method, such as Metal-Organic Chemical Vapor Deposition (MOCVD) or hydride vapour-phase epitaxy (HVPE). An additional semiconductor layer may be grown on top of the first semiconductor layer.

In various embodiments, a method deposits a diamond coating on a heat generator, such as a semiconductor material. The method provides a semiconductor material. The semiconductor material is coated with a thin layer of beryllium oxide (BeO) (e.g., using atomic layer deposition (ALD)). The method deposits a polycrystalline diamond layer onto the BeO layer at lower temperatures (e.g., using hot filament or remote plasma techniques).

The BeO layer may be 1-100 nanometers thick. The diamond layer may be between 2 microns and 90 microns thick. The semiconductor material may include a semiconductor device. The semiconductor material have a planar or three-dimensional surface. The steps of depositing BeO and diamond layers may be done on one or more surfaces. If multiple surfaces, these steps may be performed in-series or in-parallel.

In accordance with another embodiments, a coated semiconductor device includes a substrate comprising a semiconductor material, an interlayer disposed on the substrate and comprising beryllium oxide (BeO), and a diamond layer disposed on the interlayer. The BeO interlayer facilitates nucleation of the diamond layer and reduces thermal boundary resistance between the substrate and the diamond layer.

In various embodiments, the semiconductor material forming the substrate comprises gallium nitride (GaN), silicon, AlN, AlGaN, and Gallium oxide (Ga2O3), or a combination thereof. The BeO interlayer may have a thickness in the range of approximately 1 nanometer to 500 nanometers, enabling effective phonon transmission and conformal deposition without introducing excess bulk.

The diamond layer may be deposited using a low-temperature process compatible with sensitive device structures. Among other things, suitable deposition methods include hot filament chemical vapor deposition and remote plasma chemical vapor deposition. In some examples, the diamond layer comprises polycrystalline diamond having a thickness in the range of approximately 2 microns to 90 microns.

In further embodiments, the BeO interlayer may be graded or may comprise multiple sub-layers that differ in thermal conductivity, doping profile, or crystallographic properties. In such multilayered or graded configurations, the interlayer may include a graded composition or varying dopant concentration across its thickness to provide phonon impedance matching between the semiconductor substrate and the overlying diamond layer, thereby reducing phonon reflection at the interface.

The device may include one or more transistors or active device structures formed in or on the substrate prior to deposition of the BeO interlayer and diamond layer. The coating system is therefore compatible with finished or near-finished semiconductor devices.

In some embodiments, the BeO interlayer and the diamond layer are disposed on at least two opposing surfaces of the substrate, such as the top and bottom surfaces, to facilitate bi-directional thermal conduction. This allows for more effective heat dissipation in high-power device configurations.

Additionally, a surfactant material may be disposed between the substrate and the BeO interlayer, or between the BeO interlayer and the diamond layer. The surfactant may be selected from the group consisting of iridium and titanium, and may be configured as a monolayer or partial monolayer to assist with lattice relaxation or epitaxial alignment.

The BeO interlayer may also provide intermediate phonon impedance between the substrate and the diamond, which reduces thermal reflection at the interface and promotes more efficient phonon transmission. This impedance matching contributes to lower thermal boundary resistance and improved overall heat extraction performance from the semiconductor device.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIGS. 1A-1D schematically show seeding diamond for growth on a semiconductor substrate in accordance with illustrative embodiments.

FIG. 2 shows a process for depositing a diamond coating in accordance with various embodiments.

FIGS. 3A-3B schematically show cross-sections of semiconductor material having a diamond coating in accordance with illustrative embodiments.

FIG. 4 schematically shows a cross-section of another semiconductor material having a diamond coating in accordance with illustrative embodiments.

FIG. 5 schematically shows a cross-section of another semiconductor device in accordance with illustrative embodiments.

### DESCRIPTION OF ILLUSTRATIVE EMBODIMENTS

In illustrative embodiments, a thermal coating for semiconductor devices comprises beryllium oxide (BeO) and diamond. Illustrative embodiments coat a semiconductor material, such as silicon or GaN devices, with diamond to enhance thermal management. Illustrative embodiments coat the top or other surfaces (e.g., the bottom, sides, back, front) of the silicon or GaN device with a diamond layer, using a BeO interlayer to aid nucleation of the diamond and improve overall thermal conductivity. The BeO layer mitigates thermal reflection at the interface, allowing more efficient heat transfer through to the diamond. The BeO layer may also aid in nucleation of the diamond film, providing a better thermal interface with fewer voids at the interface.

Diamond is a desirable material for thermal management in semiconductor devices due to its exceptionally high thermal conductivity, which can exceed 2000 W/m. K in single-crystal form and remains above 1000 W/m·K even in high-quality polycrystalline films. This makes diamond significantly more thermally conductive than traditional heat spreaders such as copper, aluminum nitride, or silicon carbide. Incorporating diamond as a heat-spreading layer in high-power or high-frequency semiconductor devices—such as those based on gallium nitride (GaN)—can dramatically reduce junction temperatures, improve thermal gradients, and extend device reliability and lifetime. Moreover, diamond is chemically inert, mechanically robust, and radiation-hard, further supporting its integration into harsh or demanding environments common in power electronics, RF systems, and aerospace applications.

However, incorporating diamond into GaN-based devices presents several challenges. Various embodiments bond diamond to the GaN device, typically on the substrate or backside. This technique, while avoiding high-temperature processing, suffers from high thermal boundary resistance (TBR) due to poor phonon transmission at the bonded interface. Imperfect contact, microscopic voids, or the presence of adhesion layers all impede effective heat transfer. Additionally, bonded interfaces are prone to delamination due to differences in thermal expansion coefficients, and bonding is often incompatible with fully fabricated or metallized GaN devices. Bonding techniques are further limited to planar surfaces, making them unsuitable for non-planar or three-dimensional device geometries.

Alternative embodiments may grow diamond directly on the GaN device, which can in principle provide a more intimate thermal interface. However, this approach introduces its own set of limitations. First, direct diamond deposition typically requires high temperatures (often above 700-1000° C.), which exceed the thermal tolerance of GaN devices (e.g., transistors), particularly after fabrication. Moreover, diamond nucleation on GaN is difficult and inconsistent, often requiring mechanical seeding with nanodiamond particles that introduce porosity and voids at the interface, reducing thermal conduction.

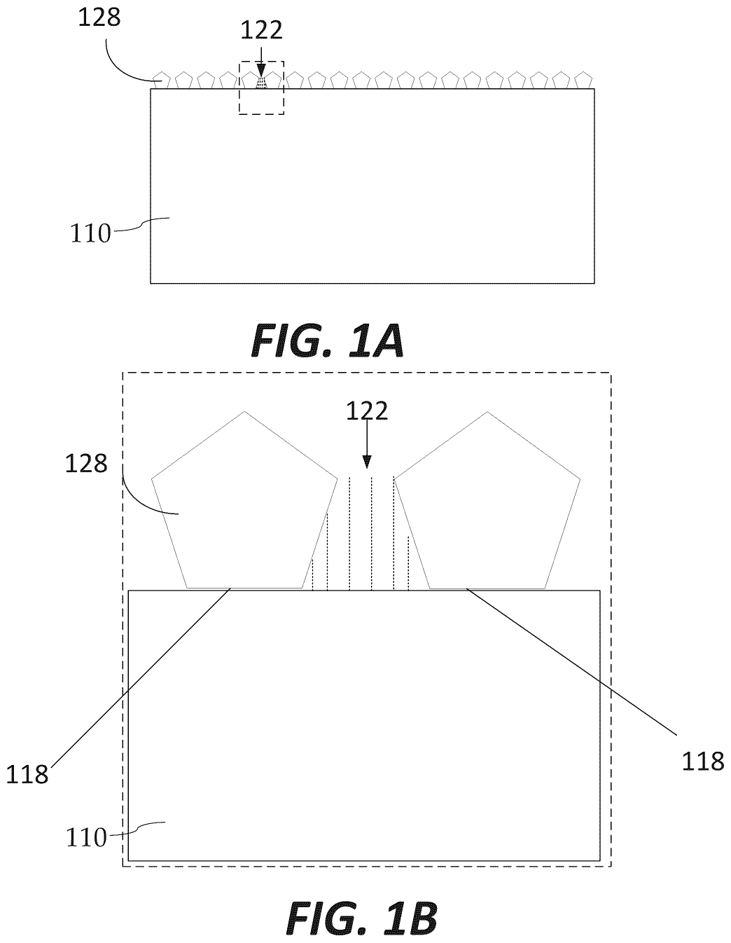

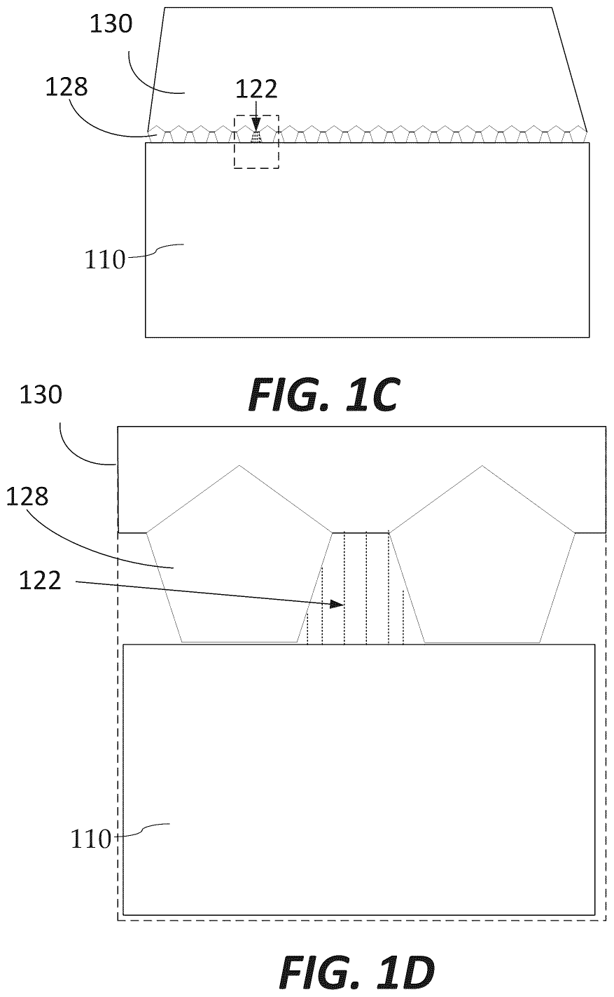

FIGS. 1A-1D schematically show a semiconductor device 100 having diamond seeds 128 positioned thereon in accordance with illustrative embodiments. FIG. 1B shows a zoomed-in portion of FIG. 1A. FIG. 1C schematically shows diamond 130 grown using the seeds 128. FIG. 1D shows a zoomed-in portion of FIG. 1C. The drawings are not to scale, but are shown merely for discussion purposes. Additionally, the seeds 128 are not necessarily pentagon shaped, but merely shown as having a particular shape for the sake of discussion. As shown, voids 122 (e.g., an air gap, or vacuum depending on process conditions), exists between the diamond seeds 128 and the substrate 110 surface 115. This leads to a reduction in the total heat extractor-semiconductor interface area (e.g., diamond-semiconductor interface area).

When depositing diamond films directly onto the semiconductor substrate 110 materials such as gallium nitride (GaN) AlN, AlGaN, Gallium oxide (Ga2O3), or silicon, various embodiments seed the surface with the nanodiamond particles 128 to promote nucleation. These seed particles 128 may be applied via spin coating or ultrasonic agitation using a solvent-based suspension. However, this technique often leads to non-uniform coverage of the underlying substrate 110 surface. Due to the random distribution and irregular shape of the seed particles 128 (not regularly sized and distributed pentagons as shown in the figures), gaps or voids 122 can remain between particles or between the particle and the substrate surface itself. These microscopic air gaps introduce porosity at the interface, which significantly degrades the thermal coupling between the substrate and the deposited diamond film.

The presence of such porosity—particularly at the interface between the substrate 110 and the diamond seed 128—restricts effective thermal conduction. Heat is only efficiently transferred through regions of direct atomic or molecular contact; in contrast, voids 122 and gaps act as thermal insulators, impeding the flow of phonons. These effects are especially problematic in high-power electronic devices, where thermal management is critical to performance and reliability. The inventors have recognized that even sub-nanometer-scale voids at the seed-substrate interface can result in measurable increases in thermal boundary resistance (TBR), ultimately limiting the efficacy of the diamond as a heat-spreading material.

Illustrative embodiments address this problem by eliminating the need for mechanical seeding altogether, through the use of a conformal BeO interlayer. The BeO layer provides a uniform, smooth, and chemically compatible surface that promotes direct nucleation of diamond, thereby avoiding the random, porous nature of traditional seed layers. As a result, diamond can be grown with greater continuity, fewer pinholes, and improved interfacial adhesion, all of which contribute to enhanced thermal conduction across the interface. The improved conformality and interface quality also allow the use of lower deposition temperatures for the diamond layer, further protecting temperature-sensitive semiconductor devices.

Thus, the seed 128 interfaces 118 lack conformality and lead to poor phonon coupling, further increasing TBR. As a result, both bonding and direct growth approaches fall short of providing an optimal thermal pathway-highlighting the need for an improved interface strategy that enables low-temperature, conformal diamond deposition with minimized interfacial resistance, such as the approach disclosed by various embodiments.

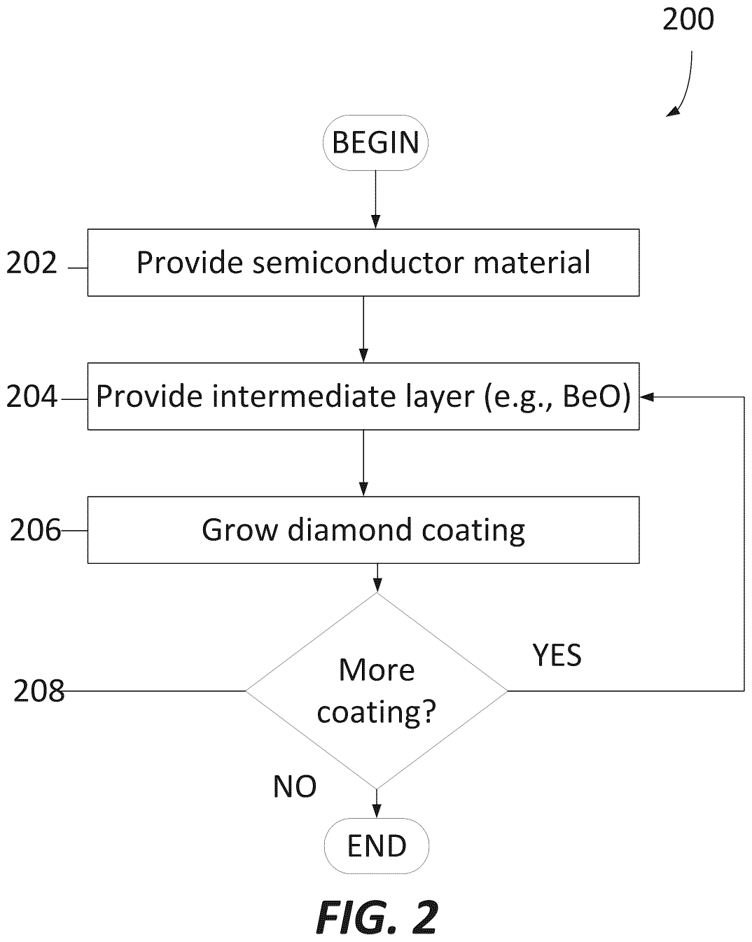

FIG. 2 shows a process 200 for forming a coated semiconductor device 100 in accordance with various embodiments. It should be noted that this method is substantially simplified from a longer process that may normally be used. Accordingly, the method shown in FIG. 2 may have many other steps that those skilled in the art likely would use. In addition, some of the steps may be performed in a different order than that shown, or at the same time. Furthermore, some of these steps may be optional in some embodiments. Accordingly, the process 200 is merely exemplary of one process in accordance with illustrative embodiments of the invention. Those skilled in the art therefore can modify the process as appropriate.

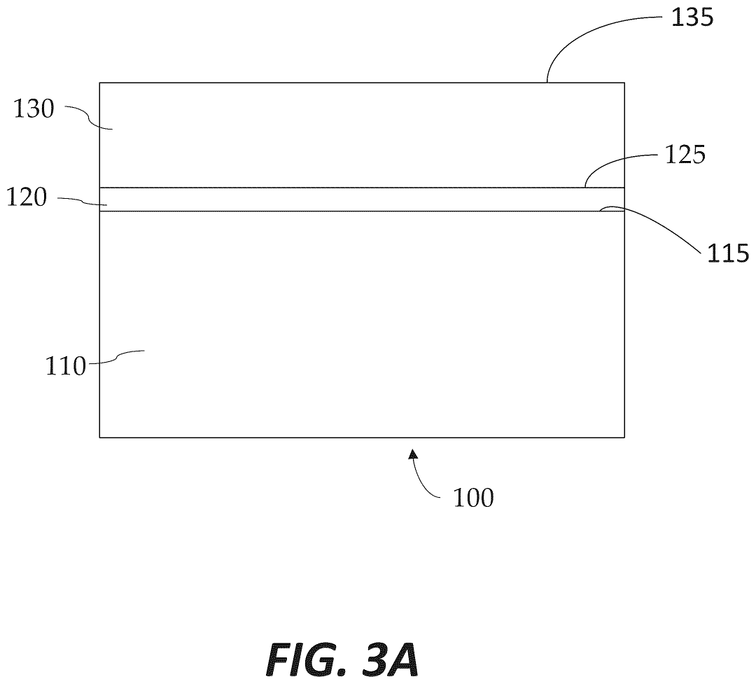

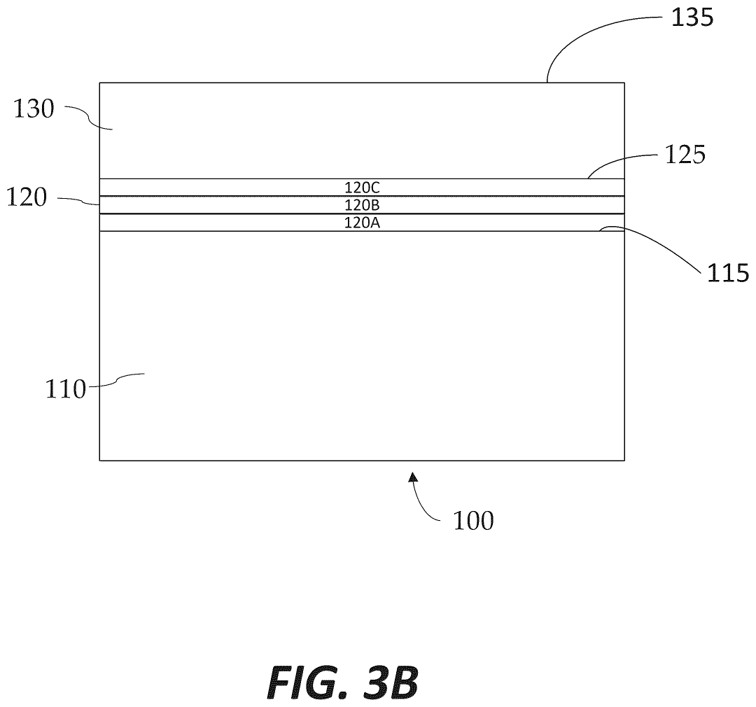

The process begins at step 202, which provides a semiconductor substrate 110 as shown in FIGS. 3A-3B. The semiconductor substrate 110 is formed from a semiconductor material, such as silicon, GaN, AlN, AlGaN, and Gallium oxide (Ga2O3) or another material. The semiconductor substrate 110 may comprise one or more devices. The semiconductor substrate 110 is not limited to planar substrate and can be applied to three-dimensional material, such as silicon MEMS structures.

The semiconductor substrate 110 refers to the underlying layer of semiconductor material, such as GaN or silicon, which may or may not include fabricated devices (e.g., transistors). Once coated with an interlayer and a diamond layer, the structure may be referred to as a coated semiconductor device. In contexts where thermal behavior is discussed, the substrate 110 or coated device 100 may also be referred to as a “heat-generating device” or “heat source.”

As will be discussed further, BeO and diamond are deposited in subsequent steps. It should be noted that in various embodiments, the BeO interlayer 120 and diamond coating 130 may be deposited on semiconductor substrate 110 either after the formation of semiconductor devices, such as transistors, or at an earlier stage, prior to device fabrication. This flexibility enables integration with a broad range of semiconductor manufacturing flows. In many implementations, it is desirable to apply the BeO 120 and diamond 130 layers after the transistors are formed, allowing the coating to serve as a post-fabrication thermal management solution without disrupting device processing. In other embodiments, the coating may be applied earlier, particularly where the device architecture or processing constraints favor early-stage thermal spreading layers.

When applied after transistor formation, the BeO 120 and diamond 130 layers are deposited onto semiconductor wafers 110 that already contain active and/or passive device structures, such as high-electron-mobility transistors (HEMTs), field-effect transistors (FETs), or diodes. These devices are typically formed through a series of standard semiconductor processing steps. For GaN-based devices, the process may begin with epitaxial growth of GaN and related heterostructures on a substrate, followed by selective doping, photolithography, and etching to define device regions. Gate dielectrics and metal electrodes are then deposited and patterned, and ohmic contacts are formed by metallization and annealing. Additional layers, such as interconnect metals or passivation coatings, may be added depending on the device design.

In such post-device-processing embodiments, the BeO interlayer 120 is conformally deposited over the completed device surface 115, including over metallized regions, passivation layers, or etched features. Due to the relatively low deposition temperatures (e.g., around 350° C.), the BeO layer 120 can be applied without damaging sensitive structures. Diamond 130 is then deposited onto the BeO layer 120 using low-temperature methods (such as hot filament or remote plasma CVD), forming a conformal heat-spreading layer. This enables enhanced thermal extraction from the completed device without interfering with electrical performance. Additionally or alternatively, in various embodiments where diamond is deposited prior to device fabrication, the thermal coating stack may be used as a foundational heat sink layer, allowing device structures to be formed on top of or adjacent to the coated surface using standard semiconductor processing techniques.

This dual integration capability-before or after device formation-offers significant manufacturing flexibility, supporting both R&D prototyping and commercial-scale production environments. It allows the disclosed thermal coating system to be implemented as a drop-in enhancement to existing process flows or as a platform-level thermal engineering strategy in new device designs.

At step 204, the semiconductor material is coated with a thin layer of BeO using, for example, atomic layer deposition (ALD) or similar techniques. By placing the BeO layer 120 between the substrate 110 and the diamond 130, thermal interface mismatch at the interface is reduced (e.g., as compared to substrate 110 directly with diamond 130), allowing more efficient heat transfer. Furthermore, BeO is a highly thermally conductive oxide. The BeO layer 120 may be single crystal. In various embodiments, when the BeO layer 120 is single crystal, similar crystallinity in the diamond 130 is desirable. However, if illustrative embodiments are targeting polycrystalline diamond 130, the BeO layer 120 may also be polycrystalline.

The BeO interlayer 120 also enables better nucleation of diamond 130 on various semiconductor substrate 110, resulting in fewer pinholes and higher quality diamond layers compared to direct deposition on the semiconductor material. The BeO layer 120 may be nanometers thick to ensure proper nucleation and thermal properties without adding significant bulk.

BeO layer 120 advantageously may be deposited on the substrate 110 (e.g., GaN) directly without requiring seeding (e.g., as shown with the diamond in FIGS. 1A-1D). This allows for excellent contact between BeO and the underlying substrate, providing a large diamond interface area as compared to diamond seeds 128 on the substrate 110. In addition to promoting high-quality diamond nucleation, the BeO interlayer offers significant benefits in reducing thermal boundary resistance through improved phonon impedance matching. At the microscopic level, heat conduction in solids—particularly in dielectric and semiconductor materials—is primarily mediated by phonons, which are quantized vibrational energy waves. When these waves encounter a boundary between two materials with dissimilar acoustic or vibrational properties, such as a GaN-diamond interface, a portion of the phonon energy is reflected rather than transmitted. This mismatch in phonon spectra leads to increased TBR, limiting the effectiveness of the thermal interface even when the materials themselves are highly thermally conductive.

The inventors have recognized that BeO, with its intermediate thermal and phonon transmission properties, can act analogously to an anti-reflective coating for phonons. The BeO interlayer 120 provides a transition zone between the low-impedance semiconductor substrate 110 (e.g., GaN) and the high-impedance diamond coating 130. By more closely matching the phonon propagation characteristics at each interface, the BeO layer 120 advantageously reduces the reflection of thermal energy and facilitates more efficient phonon transmission into the diamond layer.

This wave-based mechanism offers a distinct and complementary advantage to the chemical and structural compatibility benefits already associated with the BeO layer 120. The result is a dual-function interlayer 120 that not only supports diamond film formation but also materially improves heat flux through the stack by mitigating phonon back-scattering at interfaces. Accordingly, illustrative embodiments employing a BeO interlayer achieve improved thermal management not merely by increasing bulk conductivity, but by engineering interfacial energy transfer efficiency, a key limitation in high-performance thermal coatings.

Additionally, in some embodiments, the use of a BeO interlayer 120 not only improves thermal performance and nucleation uniformity, but also offers benefits in terms of surface finish quality of the resulting diamond coating. Experimental results have shown that diamond films 130 deposited on BeO-coated substrates exhibit a lower average surface roughness (Ra) compared to films deposited directly on GaN or silicon using conventional seeding techniques. This smoother surface may be attributed to more uniform nucleation, reduced clustering, and improved growth continuity facilitated by the conformal and chemically compatible nature of the BeO layer.

The improved surface morphology reduces or eliminates the need for extensive post-deposition polishing or planarization, which is often required in traditional diamond-on-semiconductor processes to meet integration or packaging requirements. This can lead to cost savings and reduced processing time. Importantly, while surface roughness is improved, the overall thickness uniformity of the diamond film remains substantially unchanged across the substrate, indicating that the deposition remains consistent and scalable for both planar and non-planar device architectures.

As discussed throughout the application, the interlayer 120 is preferably formed from beryllium oxide (BeO) due to its unique combination of properties that make it particularly well-suited for thermal management in semiconductor devices. BeO provides relatively high thermal conductivity among dielectrics, excellent electrical insulation, and a phonon impedance intermediate between typical semiconductor materials (e.g., GaN or silicon) and diamond. This intermediate phonon impedance helps reduce thermal boundary resistance by minimizing phonon reflection at the interface. BeO also serves as a conformal and chemically compatible nucleation surface for diamond deposition, enabling uniform growth with fewer pinholes or defects. In some embodiments, alternative materials may be used in place of BeO, either alone or in combination. In various embodiments, suitable additional or alternative interlayer materials may include aluminum nitride (AlN), hexagonal boron nitride (h-BN), magnesium oxide (MgO), silicon carbide (SiC), and other thermally conductive ceramic dielectrics or engineered multilayers. These materials are selected for their ability to support diamond nucleation, provide electrical insulation, and reduce thermal interface resistance through improved phonon coupling. In some implementations, a graded or composite interlayer may incorporate two or more such materials to optimize interface matching and deposition compatibility.

At step 206, diamond 130 is deposited onto the BeO layer 120. Advantageously, diamond 130 may be grown directly on BeO 120, providing a large contact interface. To accommodate temperature-sensitive substrates like silicon and GaN, diamond deposition is performed at lower temperatures using hot filament or remote plasma techniques, preserving substrate and avoiding the high temperatures of microwave plasma CVD. Accordingly, the deposited diamond coating is polycrystalline diamond.

While single-crystal diamond is known to possess the highest intrinsic thermal conductivity of any known bulk material-often exceeding 2000 W/m·K-its deposition requires high substrate temperatures, typically achievable only through methods such as microwave plasma chemical vapor deposition (MPCVD). These elevated temperatures, often exceeding 800° C. and sometimes reaching 1300° C., are incompatible with many semiconductor devices, particularly GaN-based power electronics or CMOS-integrated silicon substrates, which may already contain metallization layers, doped junctions, or other thermally sensitive components. Exposure to such temperatures risks damaging or degrading the performance of the underlying device.

In contrast, polycrystalline diamond films can be deposited at lower temperatures, typically in the range of 350-850° C., using hot filament or remote plasma deposition techniques. While polycrystalline diamond exhibits somewhat lower thermal conductivity than its single-crystal counterpart—due to grain boundaries, defects, and occasional graphitic inclusions—it still provides exceptionally high thermal conductivity relative to other coating materials, often in the range of 500-1500 W/m·K. More importantly, when combined with a low TBR interface—such as one enabled by a BeO interlayer—the overall thermal performance of polycrystalline diamond can approach that of higher-quality films, particularly in practical applications where interface losses dominate thermal behavior.

Accordingly, illustrative embodiments use polycrystalline to balance deposition temperature, device protection, and thermal efficiency. By minimizing interface porosity, optimizing phonon transmission through the BeO interlayer, and preserving substrate integrity at low temperatures, the system achieves effective thermal management without requiring exotic or cost-prohibitive high-temperature processes. In this way, the use of polycrystalline diamond becomes not only acceptable, but advantageous for a wide range of commercial, high-performance device integrations.

It should be noted that references to deposition temperature refer to the temperature of the substrate 110 during the deposition process, unless explicitly stated otherwise. This temperature corresponds to the thermal conditions experienced by the surface onto which the material (e.g., BeO or diamond) is being deposited. The ambient environment, plasma, or filament temperatures may be significantly higher, but are not the relevant metric for assessing thermal compatibility with underlying semiconductor devices. Substrate 110 temperature governs critical aspects of material growth, including nucleation quality, stress, grain structure, and compatibility with pre-fabricated device.

In various embodiments, the semiconductor material 110 forming the substrate 110 may include pre-fabricated semiconductor devices, such as transistors, diodes, or integrated circuit components, formed either on the surface or within the bulk of the material. For example, the semiconductor substrate may comprise a monocrystalline gallium nitride (GaN) or silicon wafer in which one or more field-effect transistors (FETs), high-electron-mobility transistors (HEMTs), or bipolar transistors have been formed using conventional fabrication techniques such as ion implantation, epitaxial growth, and photolithographic patterning. These devices may be configured for analog, digital, RF, or power applications, and may include metallization layers, dielectric passivation, and gate or contact structures. Accordingly, the interlayer 120 (e.g., BeO) and the overlying diamond 130 coating may be applied after transistor fabrication, enabling post-fab thermal management enhancement of fully functional semiconductor devices. In other embodiments, the devices may be fabricated after deposition of the interlayer and/or diamond layer, depending on process compatibility.

The diamond coating 130 may also provide chemical protection to the substrate 110, particularly in applications involving fluidic channels where the coating prevents erosion by cooling fluids. The diamond coating 130 can range from microns to tens of microns in thickness (e.g., less than 100 microns).

The process then goes to step 208, which asks if more diamond coating 130 is desired? If yes, the process returns to step 204, which deposits another intermediate layer 120, and then process to step 206, which deposits another diamond coating 130. For example, in some embodiments, the above-described process of depositing BeO and diamond layers can be applied to both the top and bottom surfaces of the semiconductor device 100, enabling bi-directional cooling. Indeed, some embodiments may apply BeO and diamond layers on all exposed surfaces. In some embodiments, the bi-directional coating may happen sequentially or in parallel.

Applying the thermal coating (i.e., BeO and diamond) to both the top and bottom surfaces of the semiconductor device to enable bi-directional cooling. This configuration is particularly advantageous in high-power or densely packed device architectures where heat generation occurs throughout the thickness of the structure, or where thermal dissipation through a single surface is insufficient. By applying a BeO interlayer and a conformal diamond coating to opposing surfaces, the thermal gradient across the device can be reduced more efficiently, thereby improving temperature uniformity and operational stability. In certain cases, additional lateral or sidewall coatings may also be applied to further enhance thermal spreading.

Furthermore, the use of BeO as the interlayer 120 material supports full encapsulation of the device 100 due to its electrical insulating properties. In various embodiments, the BeO may function as a dielectric and prevent unwanted electrical conduction paths, allowing the coating to extend over metallized or sensitive device regions without interfering with circuit operation. This encapsulation can provide not only thermal advantages, but also chemical and mechanical protection in harsh environments. The coating process is compatible with three-dimensional device geometries and can be adapted to selectively target high heat-flux regions, offering significant design flexibility for thermal engineering in advanced semiconductor packaging.

When depositing the BeO layer 120 and/or diamond layer 130, various embodiments factor in not only the absolute deposition temperature but also the thermal soak time—i.e., the duration for which the device is exposed to elevated temperatures. Many semiconductor devices, particularly those formed from GaN, are highly sensitive to thermal exposure. This sensitivity arises not merely from material degradation, but also from the presence of doped regions, gate structures, metal contacts, and other temperature-sensitive features that are susceptible to diffusion, stress, or performance shifts if subjected to prolonged heating.

Accordingly, illustrative embodiments seek to minimize both peak temperature and exposure duration during diamond deposition and intermediate layer formation. For example, while a GaN device may tolerate exposure to 450° C. for several seconds, the same device may experience degradation if exposed to 350° C. for several hours. As such, the thermal budget must be carefully managed, and the choice of deposition technique (e.g., atomic layer deposition for BeO, hot filament or remote plasma CVD for diamond) is made in view of the soak-time constraints.

This consideration is particularly critical for finished or near-finished devices, in which the performance tolerances of transistor elements are tightly bounded.

Consequently, low-temperature deposition methods that reduce soak time, even if they produce lower-quality diamond in terms of crystallinity, may still result in better overall thermal management due to improved interface engineering and substrate integrity. Illustrative embodiments thus reflect a nuanced trade-off between the thermal conductivity of the deposited material and the need to preserve underlying device performance through controlled thermal exposure.

The coating techniques described herein are amenable to both research-scale implementation and large-scale semiconductor fabrication. In some embodiments, atomic layer deposition (ALD) is used to deposit the BeO interlayer 120, particularly in a laboratory or R&D setting where precise control over film thickness and uniformity is desired. ALD enables conformal growth of nanometer-scale BeO layers on high-aspect-ratio or non-planar surfaces, which is particularly advantageous when working with microelectromechanical systems (MEMS) or three-dimensional GaN devices. However, ALD may not be optimal for high-throughput manufacturing due to its low deposition rate and batch-based architecture. Regardless, ALD may be used in high volume as needed.

Accordingly, for commercial-scale production, alternative deposition methods may be used to form the BeO layer, including physical vapor deposition (PVD), chemical vapor deposition (CVD), or sputtering. These techniques offer increased throughput and integration with existing semiconductor process lines. The deposition temperature for BeO is typically under 350° C., which is considered low temperature within the context of semiconductor processing and is compatible with GaN and silicon devices that have already undergone doping, metallization, or other high-sensitivity fabrication steps.

From a deployment perspective, the coating process described herein may be integrated into an existing semiconductor fabrication facility (“fab”). In some embodiments, the process may be used for on-site implementation, with deposition tools (e.g., for BeO and diamond) installed directly into the fab's cleanroom environment. In other embodiments, the BeO and diamond layers are applied off-site. This flexible deployment model allows the process to be adapted for both exploratory development and high-volume manufacturing scenarios.

The process 200 then comes to an end. It should be apparent that this process provides a number of advantages discussed herein. As an example, the process removes the need for a seeded layer to promote nucleation. As discussed above, the seeded method introduces microscopic voids and air gaps between the seed particles and the underlying substrate surface due to irregular seed shape, size variation, and incomplete surface coverage. These localized porosity regions result in non-uniform contact at the interface, meaning that thermal energy can only be transferred through discrete contact points where diamond is physically touching the substrate. The remainder of the interface, consisting of voids or low-conductivity gas-filled regions, acts as a thermal bottleneck, contributing substantially to increased thermal boundary resistance. Illustrative embodiments advantageously replace the seeding step with the conformal beryllium oxide (BeO) interlayer 120, which eliminates these voids and enables direct, uniform nucleation of diamond 130, thereby creating an intimate, continuous thermal interface. This not only improves phonon coupling across the interface but also enhances overall heat extraction efficiency from the semiconductor device 110.

In various embodiments, the beryllium oxide (BeO) interlayer 120 is intimately coupled to the underlying semiconductor substrate 110, providing a continuous, conformal interface that significantly enhances thermal conduction. Unlike seeded diamond deposition methods that may involve discrete nucleation sites or physical bonding with interfacial voids or surface roughness, the use of a conformally deposited BeO layer-such as by atomic layer deposition (ALD), physical vapor deposition (PVD), or sputtering-promotes uniform coverage and atomic-level proximity between the materials. This intimate coupling minimizes the formation of air gaps, voids, or low-conductivity interfacial regions, thereby reducing thermal boundary resistance (TBR). Enhanced phonon transfer across the interface is enabled by both the physical continuity of the layers and the intermediate phonon impedance of the BeO, which reduces phonon reflection at the interface. In various embodiments, the coated device 100 exhibiting such intimate coupling may be characterized by a high percentage of physical contact area between the substrate and the interlayer—e.g., at least 90% or more, and in some embodiments greater than 95% contact area across the interface.

FIG. 3A schematically shows a diamond coated heat source 100 in accordance with illustrative embodiments. FIG. 3A is not necessarily to scale. In various embodiments, the heat may be generated by the semiconductor substrate 110, which in some cases may include one or more semiconductor devices, such as transistors or integrated circuit components. Thus, in various embodiments, the semiconductor substrate 110 may be a heat generator. The semiconductor substrate 110 has an interface 115. Although shown as planar, the substrate 110 may have a three-dimensional interface 115. As described previously, the substrate 110 may comprise a MEMS structure or another type of etched semiconductor structure. Accordingly, the substrate 110 may function as a heat-generating or heat-dissipating device, depending on the application.

Diamond material is highly thermally conductive. Therefore, it is advantageous to use diamond as a heat spreading material. However, as described previously, it is difficult to nucleate diamond directly on semiconductor material, and the quality tends to be poor. The inventors determined that diamond nucleates better on the heat source 110 (formed of any material, e.g., copper, silver, SiC, gallium oxide, etc.) if BeO is used as an intermediate layer 120. Thus, the interface layer 120 allows for better nucleation of diamond material with fewer pinholes, and better overall quality. Furthermore, the diamond layer 130 grows better on BeO than on other materials because diamond is epitaxially compatible with BeO.

Despite diamond being one of the highest thermally conductive materials, the inventors advantageously determined that heat dissipation from the heat source 110 is surprisingly improved by using a thin intermediate layer of a lower thermally conductive material between the heat source 110 and the diamond layer 130.

The inventors believe that the improved thermal dissipation from the heat source 110 is due to reductions in thermal interface mismatch. When two materials with different thermal properties (e.g., thermal conductivity, phonon spectra) are in contact, there is a mismatch in how phonons transfer energy across the interface, leading to thermal resistance. Similar to how light reflects and refracts at a boundary with different optical indices, phonons (quantized vibrations that carry heat) can be partially reflected at the boundary between two materials with different phonon spectra. This reflection leads to increased thermal resistance. The inventors thus determined that the introduction of an interface layer 120 with intermediate thermal properties (e.g., BeO) can help in “matching” the phonon spectra, reducing reflection and thereby decreasing the TBR.

FIG. 3B shows another diamond coated heat source 100 in accordance with illustrative embodiments. Although a single layer of BeO is shown in FIG. 3A, illustrative embodiments may have multiple interface layers, preferably providing a graded thermal interface as shown in FIG. 3B. In some embodiments, the interface layer 120 formed from beryllium oxide may be implemented as a graded or multi-layered structure 120A-120C to further optimize thermal performance, stress distribution, or nucleation behavior. A graded BeO interlayer 120 may exhibit a gradual variation in one or more properties-such as composition, crystallinity, grain size, or dopant concentration-across its thickness. For example, the BeO layer may be doped with varying levels of a secondary element (e.g., titanium or iridium) from the substrate-facing side to the diamond-facing side to better match the lattice constants or phonon spectra of the adjoining materials. This gradation can reduce phonon reflection at each interface and facilitate smoother thermal transmission, analogous to impedance matching in RF systems or anti-reflective coatings in optics.

In other embodiments, the interlayer 120 may comprise discrete sub-layers (e.g., 120A-120C) of BeO or BeO-based compositions, each having distinct material properties. For instance, a first sub-layer 120A may prioritize adhesion and lattice conformity with the semiconductor substrate, while a second sub-layer 120B is optimized for thermal conductivity and diamond nucleation. These stacked configurations may also include intermediate materials or adhesion promoters between sub-layers to further improve structural integrity or stress relief. Whether continuously graded or discretely layered, these variations allow for tailored thermal impedance profiles, which can be especially advantageous for non-planar or high-power-density device geometries. The overall structure remains thin (e.g., less than 1 micron), preserving the proximity of the diamond coating to the underlying heat source 110 while enhancing interface performance.

Although FIG. 3B shows graded layers 120A-120C, it should be understood that various embodiments may have fewer or more graded layers. Illustrative embodiments are not intended to be limited to the number of layers shown in the figures. Other embodiments may use a single interface layer 120. Regardless, illustrative embodiments reduce resistance to heat transmission, and result in less thermal reflectance at that interface (compared to directly coupling heat generator 110 with diamond layer 130). Accordingly, more heat is passed through to the diamond 130 by adding one or more interface layers 120.

The interface later 120, which is preferably formed from BeO, is deposited over the interface 115. The BeO may be deposited, for example, use ALD. The BeO may advantageously be deposited on any heat source 110 (e.g., a foreign substrate, including silicon). This provides for a broad variety of materials on which diamond may ultimately be coated. For the intermediate BeO layer 120 to advantageously have desirable thermal conductivity properties and proper nucleation of the diamond, the deposited layer is preferably nanometer scale (e.g., 1 nm-200 nm). While the layer could be thicker, the inventors believe that there is limited benefit, and perhaps a reduction in performance, for thicker intermediate layer 120.

As described previously, it is highly desirable to remove heat from the heat generator 110. The ability to pull heat from the coated device 100 is dependent on the conductivity of the material that is pulling heat out of the device/junction and the distance that the material is from the point of heat generation (e.g., the junction in a semiconductor device). In some embodiments, the ability to pull heat from the coated device 100 may be represented by the following formula, where k is the material conductivity, qᵥ is the rate at which energy is generated per volume of the medium, ρ is the density, and cₚ is the specific heat capacity.

$$\frac{\partial }{\partial x} ( k \frac{\partial T}{\partial x} ) + \frac{\partial }{\partial y} ( k \frac{\partial T}{\partial y} ) + \frac{\partial }{\partial z} ( k \frac{\partial T}{\partial z} ) + {q}_{v} = ρ {c}_{p} \frac{\partial T}{\partial z} \qquad ( 1 )$$

For simplicity, near the junction, heat conductivity is approximately proportional to 1/r². Accordingly, illustrative embodiments advantageously grow the BeO layer 120 thin (while still providing sufficient material for epitaxial growth), so as to reduce the distance of the diamond layer 130 from the heat generator 110.

Preferably, the interface layer 120 is thin (e.g., a less than 1 micron thick) such that the distance between the heat generator 110 and the diamond 130 is small. Illustrative embodiments may thus be used to grow polycrystalline stacks (e.g., polycrystalline diamond, BeO, and/or GaN).

This advantageously reduces the need for complex/thick heterostacks and/or diamond bonding methods for coupling diamond to GaN. Various embodiments provide a heat generator base layer 110. The heat generator base layer 110 is oriented such that a top surface of the base layer 110 is a base growth surface 115. A BeO layer 120 is grown over the base growth surface 115. The BeO layer 120 also defines an intermediate growth surface 125, on which the diamond layer 130 is grown.

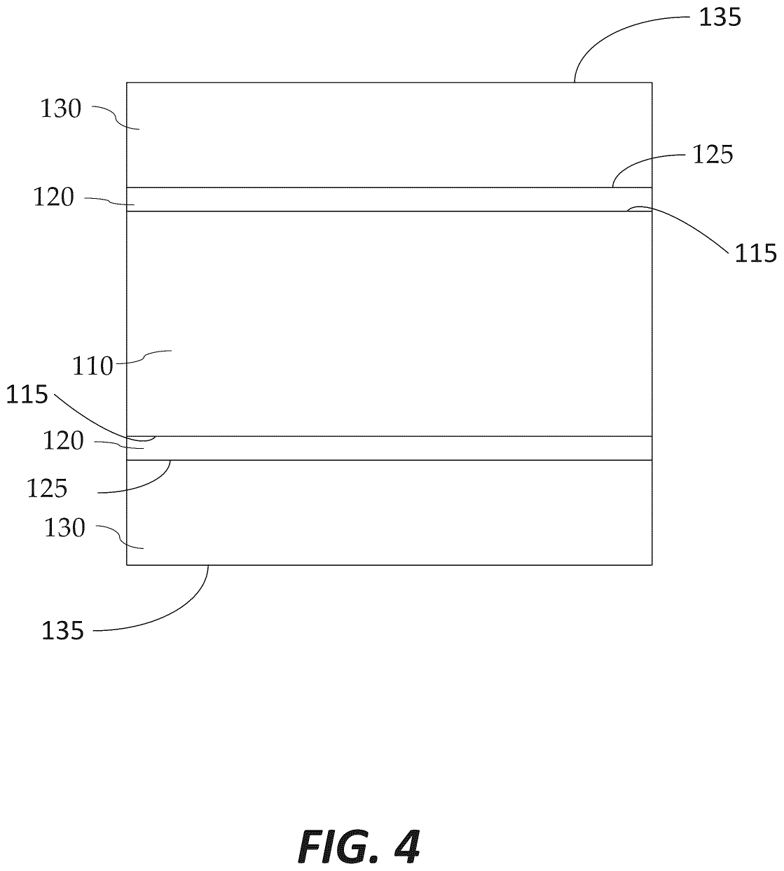

The polycrystalline diamond coating 130 is deposited over the interface layer 120 material (or other heat generating material). As shown in FIG. 4, some embodiments can put diamond on the bottom and the top of the device, and cool the device down from both directions. Additionally, or alternatively, interface layer 120 and diamond layer 130 may be grown on all or any sides (e.g., top, bottom, front, back, left, and/or right).

In contrast to some other diamond deposition methods which grow semiconductor (e.g., GaN) on diamond, this method grows diamond on semiconductor (e.g., GaN) using an intermediate layer 120. However, the heat generator 110 is exposed to the diamond growth temperatures. Accordingly, illustrative embodiments use lower temperature deposition methods to prevent damaging the heat generator 110 (e.g., GaN device). Lower temperature coating methods result in a polycrystalline diamond layer 130. Thus, various embodiments preferably use growth temperatures from a hot filament reactor or a remote plasma.

With a hot filament reactor, the substrate temperature may be set between 450° C. to 850° C., although lower is possible (e.g., 350-400C). The precise temperature can vary depending on the specific conditions and the desired properties of the diamond film. The filament temperature generally ranges from 1800° C. to 2200° C. The filament is heated to a high temperature to activate the gas mixture (usually a combination of methane and hydrogen), which then dissociates and deposits diamond on the substrate.

With a remote plasma reactor, the substrate temperature is typically between 500° C. and 900° C. This method allows for lower substrate temperatures compared to the hot filament method due to the activation of gases occurring in the plasma rather than through direct thermal means. The plasma itself can reach temperatures of several thousand degrees Celsius. However, the substrate (e.g., the semiconductor device 110) temperature remains relatively lower because the plasma is generated remotely, and the energy is transferred to the substrate through reactive species rather than direct heating.

This is contrast to higher temperature methods, such as Microwave Plasma Chemical Vapor Deposition (MPCVD). MPCVD is a widely used method for diamond deposition due to its ability to produce high-quality diamond films. The typical substrate temperature is generally between 700° C. and 1300° C., but temperatures can go as high as 1400° C. for high quality diamond. The substrate temperature provides growth of high-quality diamond crystals. The exact temperature can be adjusted based on the specific requirements of the film's properties. However, illustrative embodiments use polycrystalline diamond as a heat spreader, and therefore, do not necessarily require the higher temperatures typically achieved by MPCVD. Some prior methods use microwave plasmas that are very hot and could damage the heat generator 110. However, when growing semiconductor (e.g., GaN) on diamond, it isn't a problem because the high-quality diamond is grown and then allowed to cool. This is not possible when growing diamond on the heat generator 110.

In various embodiments, the diamond layer 130 is at least a few microns thick (e.g., 2-10 microns), up to 90 microns thick.

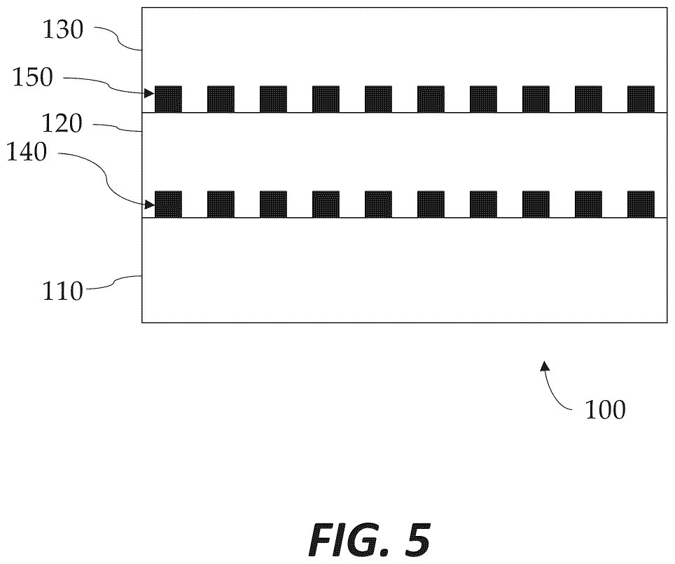

FIG. 5 schematically shows an alternative embodiment of the coated semiconductor device 100 in accordance with illustrative embodiments. In various embodiments, the semiconductor substrate 110 may include a surfactant 140 configured to aid in lattice relaxation or aid in the epitaxial formation of an epitaxial layer 120 over the base layer 110. The surfactant 140 may be provided in the form of a fractional monolayer that is applied to the base layer 110 (i.e., on the growth surface 115 or the growth surface 125) prior to growth of the subsequent layer (e.g., prior to the growth of the epitaxial layer 120 or the diamond layer 130). The surfactant may be applied, for example, using physical vapor deposition (e.g., sputtering or thermal evaporation) or atomic layer deposition (ALD). The surfactant 140 may aid in the formation of a single-crystal epitaxial layer 120 over the single-crystal base layer 110. The surfactant 140 may have a lattice constant between the lattice constant of the two layers that it interfaces with (e.g., between the lattice constant of the base layer 110 and the lattice constant of the epitaxial layer 120).

In some embodiments, the surfactant 140 may include iridium or titanium, among other things. The surfactant 140 may be a monolayer—i.e., having the thickness no greater than one molecule, or in some cases, no greater than one atom. In some embodiments, the surfactant 140 may include more than one material deposited between the base layer 110 and the epitaxial layer 120. The surfactant 140 may be configured as a partial monolayer such that the surfactant 140 covers only a portion of the base layer 110 over which the epitaxial layer 120 forms. In some embodiments, the surfactant 140 is a partial monolayer covering 10-75% of the epitaxial layer-facing surface of the base layer 110. In some embodiments, the surfactant 140 is a partial monolayer covering 25-50% of the epitaxial layer-facing surface of the base layer 110.

It should be apparent that even with the surfactant 140, the epitaxial layer 120 and the base layer 110 are in intimate contact. The layers 110 and 120 are atomically bonded, except in some places where bonding is interrupted by atoms from the surfactant 140. However, some embodiments may not include the surfactant 140. In such embodiments, the growth between the epitaxial layer 120 and the base layer 110 may be pseudomorphic.

The epitaxial layer 120 is epitaxially grown over the base layer 110. Accordingly, the epitaxial layer 120 permits the deposition of an otherwise high-defect and difficult to nucleate diamond layer 130 over the base layer 110. The epitaxial layer 120 may have a thickness within a range inclusive of 3-500 nm, or a range inclusive of 5-15 nm, among other things. In some embodiments, the epitaxial layer 120 is formed directly over the base layer 110 without an intermediate layer. While BeO is thermally conductive, it is not as thermally conductive as diamond. Therefore, illustrative embodiments preferably limit the thickness of the BeO layer 120. However, sufficient structure is required to allow for subsequent growth of the semiconductor GaN layer 130. The inventors have found that BeO films of less than 3 nm are not effective for subsequent epitaxial growth thereon and tend to be defective. Furthermore, the inventors have found that BeO films over 500 nm adds thickness that significantly undesirable impacts the thermal conductivity of the diamond layer.

Among other ways, illustrative embodiments may use atomic layer deposition, liquid-phase epitaxy, molecular beam epitaxy, pulsed laser deposition, high power impulse magnetron sputtering (HiPIMS), metal organic chemical vapor deposition (MOCVD), standard chemical vapor deposition, or other techniques to form layers on other layers of the coated device 100, such as forming the epitaxial layer 120 over the base layer 110 (also referred to as the heat generator 110). Those skilled in the art may use still other known techniques to form the epitaxial layer 120 over the base layer 110.

Epitaxial formation of the epitaxial layer 120 onto the base layer 110 may include crystal growth or material deposition in which new crystalline layers of the epitaxial layer 120 are formed with one or more well-defined orientations with respect to the base layer 110, which acts as a crystalline seed layer. Epitaxial deposition causes the deposited epitaxial layer 120 to take on a crystalline structure bearing similar lattice constants or multiples thereof of the base layer 110, which, is polycrystalline in various embodiments.

The epitaxial layer 120 may comprise or consist of a material having high thermal conductivity. The epitaxial layer 120 may comprise or consist of BeO, thereby permitting the epitaxial formation of GaN onto a diamond base layer 110 using a material with high thermal conductivity. In other embodiments, the epitaxial layer may include BeO, as well as additives such as iridium or titanium. When epitaxially formed on a polycrystalline heat generator layer 110, the BeO epitaxial layer 120 may also be polycrystalline. The BeO may or may not be polycrystalline, depending on process conditions and surface structure. Various embodiments may use different crystallinities of BeO and substrate/heat generator. However, in various embodiments, the diamond may be polycrystalline.

Additionally, various embodiments may include a surfactant 150 configured to aid in lattice relaxation or aid in the epitaxial formation of a layer, such as diamond layer 130, over the epitaxial layer 120. In some embodiments, the surfactant 150 may be configured to have a lattice constant between the lattice constant of the epitaxial layer 120 and the lattice constant of the diamond layer 130. In some embodiments, the coated device 100 does not include the surfactant 150, and grows the diamond layer 130 directly over the epitaxial layer 120 (e.g., BeO layer) without the surfactant 150.

The surfactant 150 may include iridium or titanium, among other things. As with the other surfactant 140, the surfactant 150 may be a monolayer including a partial monolayer. The surfactant 150 may have more than one material deposited between the diamond layer 130 and the epitaxial layer 120. As a partial monolayer, the surfactant 150 may cover only a portion of the epitaxial layer 120 over which the diamond layer 130 forms. In some embodiments, the surfactant 150 is a partial monolayer covering at least 10% of the seed layer-facing surface of the epitaxial layer 120. In some embodiments, the surfactant 150 is a partial monolayer covering 10-75% of the growth surface 125 of the epitaxial layer 120. In some embodiments, the surfactant 140 is a partial monolayer covering 25-50% of the growth surface 125 of the epitaxial layer 120.

In some embodiments, the coated device 100 may include more or fewer layers. For example, the coated device 100 may not include the surfactant 140, the surfactant 150, and/or the diamond layer 130. In another example, the coated device 100 may include the semiconductor base layer 110, the surfactant 140, and the epitaxial layer 120. In another example, the coated device 100 may include the base layer 110, the epitaxial layer 120, and the diamond coating 130. In yet another example, the coated device 100 may include the base layer 110, and the epitaxial layer 120 having a patterned growth surface 125.

It is contemplated that the various aspects, features, processes, and operations from the various embodiments may be used in any of the other embodiments unless expressly stated to the contrary. Certain operations illustrated may be implemented by a computer executing a computer program product on a non-transient, computer-readable storage medium, where the computer program product includes instructions causing the computer to execute one or more of the operations, or to issue commands to other devices to execute one or more operations.

As used in this specification and the claims, the singular forms “a,” “an,” and “the” refer to plural referents unless the context clearly dictates otherwise. For example, reference to “the layer” in the singular includes a plurality of layers, and reference to “the device” in the singular includes one or more devices and equivalents known to those skilled in the art. Thus, in various embodiments, any reference to the singular includes a plurality, and any reference to more than one component can include the singular.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein.

It is, therefore, to be understood that the foregoing embodiments are presented by way of example only and that, within the scope of the appended claims and equivalents thereto, inventive embodiments may be practiced otherwise than as specifically described and claimed. Illustrative embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure. Disclosed embodiments, or portions thereof, may be combined in ways not listed above and/or not explicitly claimed. Thus, one or more features from variously disclosed examples and embodiments may be combined in various ways. For example, it is to be understood that the present disclosure contemplates that, to the extent possible, one or more features of any embodiment can be combined with one or more features of any other embodiment.

Various inventive concepts may be embodied as one or more methods, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Although the above discussion discloses various exemplary embodiments of the invention, it should be apparent that those skilled in the art can make various modifications that will achieve some of the advantages of the invention without departing from the true scope of the invention.

What is claimed is:

1. A method for depositing a diamond coating on a semiconductor material comprising:
coating a semiconductor material with a layer of beryllium oxide (BeO) having a thickness of between about 2 nanometers and about 200 nanometers;
depositing a polycrystalline diamond layer onto the BeO layer.

2. The method of claim 1, wherein the semiconductor material is selected from the group consisting of silicon, aluminum nitride (AlN), aluminum gallium nitride (AlGaN), gallium oxide (Ga2O3) and gallium nitride (GaN), and the BeO layer is intimately coupled with the semiconductor material.

3. The method of any of the previous claims, wherein the BeO layer is coated on the semiconductor material using atomic layer deposition (ALD), CVD, PVD, sputtering, and/or pulsed laser deposition (PLD), wherein the BeO layer is 1-100 nanometers thick.

4. The method of claim 1, wherein the diamond layer is between 2 microns and 90 microns thick, in particular less than 12 microns thick.

5. The method of claim 1, further comprising depositing the BeO and diamond layers on both the top and bottom surfaces of the semiconductor device.

6. The method of claim 1, wherein the BeO layer is configured to reduce thermal interface mismatch at the interface between the semiconductor material and the diamond layer.

7. The method of claim 1, wherein the BeO layer is between about 2 nanometers to about 200 nanometers thick and deposited using atomic layer deposition (ALD).

8. The method of claim 1, wherein the diamond layer is between 2 microns and 90 microns thick.

9. The method of claim 1, wherein the semiconductor material is selected from the group consisting of silicon and gallium nitride (GaN).

10. A diamond-coated device comprising:
a heat generator;
a beryllium oxide (BeO) layer formed over the heat generator; and
a polycrystalline diamond coating disposed on the BeO layer.

11. The coated semiconductor device of claim 10, wherein heat generator is a semiconductor device.

12. The coated semiconductor device claim 10, wherein the semiconductor device is formed of silicon or GaN.

13. The coated semiconductor device claim 10, wherein the BeO layer has a thickness between about 1 nanometer and about 500 nanometers.

14. The coated semiconductor device claim 10, wherein the diamond layer is deposited using a low-temperature deposition process comprising hot filament chemical vapor deposition and remote plasma chemical vapor deposition.

15. The coated semiconductor device claim 10, wherein the diamond layer is polycrystalline diamond having a thickness between about 2 microns and about 90 microns, in particular wherein the polycrystalline diamond has a thickness of less than 12 microns.

16. The coated semiconductor device claim 10, wherein the BeO layer is graded or comprises multiple sub-layers having different thermal or structural properties.

17. The coated semiconductor device of claim 16, wherein the BeO layer comprises a graded composition or variable doping concentration across its thickness.

18. The coated semiconductor device claim 10, further comprising one or more transistors formed in or on the substrate prior to deposition of the BeO layer and the diamond layer.

19. The coated semiconductor device claim 10, wherein the BeO layer and the diamond layer are disposed on at least two opposing surfaces of the substrate to enable bi-directional thermal conduction.

20. The coated semiconductor device claim 10, wherein the BeO layer comprises a surfactant material selected from the group consisting of iridium and titanium, disposed between the substrate and the BeO layer, or between the BeO layer and the diamond layer.
